(19) United States
(12) Patent Application Publication
(10) Pub. No.: US 2012/0290117 A1
(43) Pub. Date: Nov. 15, 2012

(54) VIBRATION COMPENSATION DURING TRIM AND FORM AND MARKING

(76) Inventors: Jane-Yau Wang, Tu-Cheng City (TW); Chih-Chung Chen, Chung Ho City (TW); Chih-Hsien Lin, Taipei (TW)

(21) Appl. No.: 13/107,401

(22) Filed: May 13, 2011

(51) Int. Cl. H01L 21/02

(52) U.S. Cl. 700/108; 700/286

(57) ABSTRACT

A method for forming indicia on a semiconductor device package, such as laser marked or ink stamp marked indicia. The method can be performed on an apparatus, such as a production apparatus, which forms the indicia as well as performs semiconductor device trim and form operations. An embodiment of the present teachings ensures that the indicia marking process at a laser marking station does not occur simultaneously with the device trim and form operations at a trim and form station. Trim and form operations, particularly using a ram press, can impose vibrations on the laser marking station. Ensuring that laser marking does not occur simultaneously with trim and form operations removes the negative effects of vibration on the laser marking station.

### FIELD OF THE EMBODIMENTS

The present teachings relate to the field of semiconductor device manufacture, and more specifically to package trim and form equipment and marking equipment, methods of trim and form and marking, and methods of forming semiconductor devices including trim and form and marking.

### BACKGROUND OF THE EMBODIMENTS

Packaging a semiconductor chip can include attaching a plurality of individual semiconductor chips to a leadframe. The plurality of chips on the leadframe can be individually encapsulated by molding each chip in plastic resin. After encapsulation, a deflash process can be performed to remove excess plastic resin which can be extruded under pressure between mold halves. Dam bars which help contain the encapsulation during the molding process are trimmed, leads of each device can be formed, then tie bars which hold each individual device to the leadframe are cut to singularize each device from the plurality of other packaged chips.

After the packaged chips are singularized from the leadframe, each device package can be marked with indicia such as wafer data, production lot data, a company logo, device speed, device configuration, manufacturing flow, etc. The indicia can be human readable (e.g., images or alphanumeric characters), or device readable (scannable) including, for example, one dimensional (1D) barcode data or two dimensional (2D) barcode data. The data is typically stamped on the device package using an ink stamping process or engraved on the package using a laser marking system, or both.

If the marking indicia is not crisply and accurately produced on the package, a customer may view the device as being of inferior quality. In the case of 1D or 2D barcodes, a poor quality mark can render any coded data as unreadable by a scanner.

### SUMMARY OF THE EMBODIMENTS

During an examination of the causes of unclear, poor quality marks on semiconductor packages, the inventors determined that vibrations on the marking equipment was contributing to poor marks. Vibration damping has been attempted using rubber pads under the feet of the marking equipment. Additionally, attempts were made to isolate various equipment subassemblies to reduce vibration, but vibration was still found to be a contributor to poor marking indicia on semiconductor device packages.

The inventors therefore attempted to determine the root causes of the vibrations which resulted in poor marking indicia rather than making further attempts to reduce the effects of the vibration. As a result of this examination, the inventors developed a new method for semiconductor device formation which increases the percentage of devices having acceptable semiconductor device package marking indicia. The marking indicia can include human readable indicia such as images and alphanumeric characters, as well as scannable indicia such as 1D barcodes and 2D barcodes formed using, for example, a laser marking apparatus and/or an ink stamping apparatus. This new method can result in decreased rework and scrap, and therefore can decrease manufacturing costs.

### BRIEF DESCRIPTION OF THE DRAWINGS

The accompanying drawings, which are incorporated in and constitute a part of this specification, illustrate embodiments of the present teachings and together with the description, serve to explain the principles of the disclosure. In the figures:

FIG. 1 is a flow diagram of various stages which can be used with an embodiment of the present teachings;

FIG. 2 is a flow diagram of various stages which can be used with another embodiment of the present teachings;

FIG. 3 is a flow diagram of various stages which cab be used with another embodiment of the present teachings;

FIG. 4 is a schematic depiction of an apparatus, for example a production apparatus, which performs marking using a laser marking process or an ink stamping process as well as semiconductor device package trim and form operations, for example using a ram press; and

FIG. 5 is a perspective view of a semiconductor device which includes a laser marked or ink stamp marked package.

It should be noted that some details of the FIGS. have been simplified and are drawn to facilitate understanding of the present teachings rather than to maintain strict structural accuracy, detail, and scale.

### DESCRIPTION OF THE EMBODIMENTS

Reference will now be made in detail to the embodiments of the present teachings, examples of which are illustrated in the accompanying drawings. Wherever possible, the same reference numbers will be used throughout the drawings to refer to the same or like parts.

The present can include implementation of a software solution which reduces the negative effects of vibration during semiconductor device package marking. Package marking can include, for example, the use of an indicia marking apparatus incorporating a laser marking (laser etching) process or an ink stamping process. While the present teachings are described below with reference to a laser marking apparatus for simplicity of explanation, it will be understood the process can be adapted for use with an ink stamping process, or for a process using both laser marking and ink marking.

In an embodiment, package trim and form processing as well as laser marking are integrated into separate stations of a single production apparatus. During package trim and form operations, a ram press is used to trim package dam bars and tie bars to singularize devices from a leadframe, and to form package leads. In an embodiment, software control of the trim and form and laser marking apparatus ensures that laser marking is not performed simultaneously when the ram press is performing active trim and form operations. Control of the equipment such as the laser marking station and the ram press station can be controlled through programmable logic control (PLC) software. Thus while overall vibration caused by the ram press portion of the apparatus is not reduced the negative effects of the vibration of the ram press on the laser marking process is decreased or eliminated.

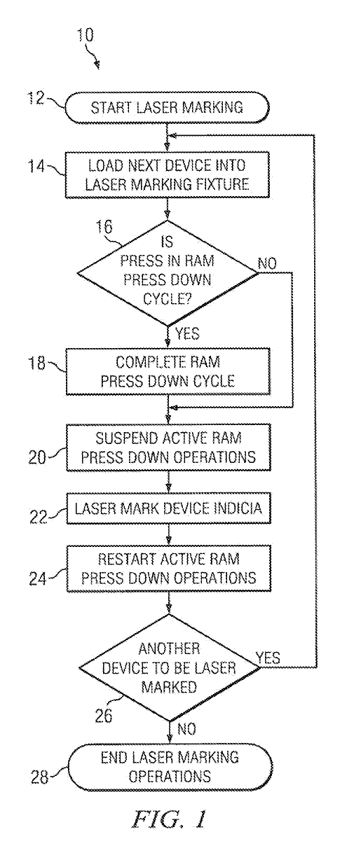

FIG. 1 is a flow chart depicting an embodiment 10 of the present teachings. In this embodiment, a laser marking cycle is initialized 12, and a packaged device is loaded into a laser marking chuck or fixture 14. A packaged device can include a semiconductor die packaged in plastic resin or ceramic, or another packaged device. Prior to laser marking the device, the software performs a check 16 to determine whether the ram press is performing trim and form operations, referred to herein as “ram press down”. If ram press down operations are being performed, the ram press down cycle can be completed 18, then additional ram press down operations are suspended 20, for example by issuing a “busy” signal from the PLC software to the ram press station. If ram press down operations are not being performed, ram press down operations are suspended immediately 20, for example by issuing a busy signal. During suspended ram press down operations, other operations which do not adversely affect laser marking processes (i.e., nonactive processes), such as loading another device into the ram press, can continue to reduce impact on production throughput.

After suspending ram press down operations 20, the device is laser marked 22 with desired indicia. The indicia can include human readable marks such as company logos and alphanumeric characters. The indicia can further include coded marks which can be scanned and read using a scanner, such as numeric-only barcodes, alphanumeric (1D) barcodes, 2D barcodes, and other coded indicia. After placement of the laser mark on the packaged device, active ram press operations can be restarted or continued 24, for example by issuing a “standby” signal by the PLC software to the ram press station, indicating that the laser marking station is in a standby or idle mode.

Next, a check is performed to see if another device is waiting to be later marked 26. If no other device is waiting to be marked, the laser marking cycle is terminated 28 until another device needs to be marked. If it is determined that another device needs to be marked at 26, the next device is loaded into the laser marking fixture 14, and the process begins again.

In the process of FIG. 1, software control of the production apparatus determines whether ram press down operations are being performed prior to laser marking a device. This embodiment can provide a ram press priority process which gives precedence to ram press processing, for example if ram press down operations generally require longer to perform per device than laser marking operations. In cases where ram press operations require substantially longer per device than laser marking operations, software control can be programed to suspend active ram press down operations only after completing ram press down operations on more than one device. In an implementation of this particular embodiment, the text of box 18 of FIG. 1 could be replaced by “complete X number of active ram press down cycles,” where “X” is greater than one. For example, if ram press down operations take three times longer per device than laser marking operations, X can equal three to allow active ram press operations to be completed on three device packages before laser marking a device. This may ensure that ram press operations are performed at a sufficient rate that the implementation of the present teachings do not adversely affect production throughput.

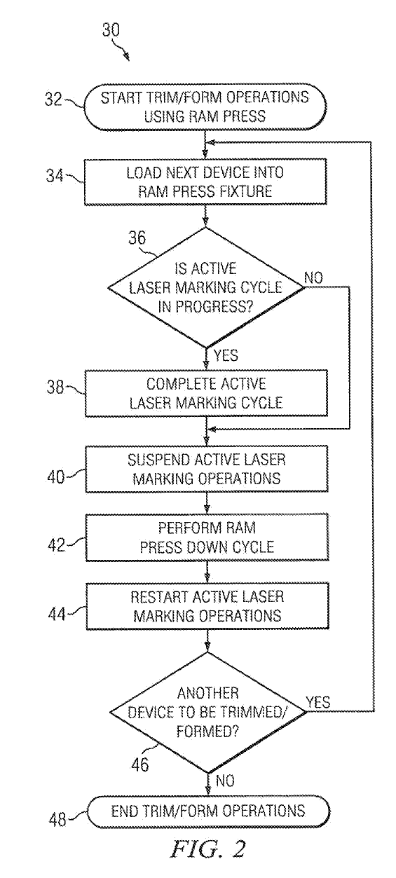

Another embodiment 30 is depicted in FIG. 2. In this embodiment, ram press down operations are initiated 32, and a packaged device is loaded into a ram press fixture 34. Prior to initiating ram press down operations, software control determines whether a device is being laser marked 36. If so, the laser marking process is completed 38, then active laser marking operations are suspended 40, for example through issuance of a “busy” signal to the laser marking station by the PLC software. If it is determined at 36 that laser marking procedures are not in progress, active laser marking operations are suspended directly at 40. During suspension of active laser marking operations at 40 nonactive laser marking operations such as loading a device into the laser marking fixture, aligning a device in the fixture to the laser using, for example, an optical system (not depicted), and moving a marked device out of the fixture can continue to minimize impact on production throughput.

After suspending active laser marking operations 40, ram press down operations, such as forming device leads and trimming, dam bars and tie bars are performed 42. Once ram press down operations are completed, active laser marking operations are restarted 44, for example by issuing a “standby” signal to the laser marking station by the PLC software, indicating that the ram press station is in a standby or idle mode. Software control then determines if another device is waiting to be trimmed and formed 46. If so, the next device is loaded into the ram press fixture 34 and the process continues as described above. If all ram press down operations have been completed, trim and form operations are terminated 48.

In the process of FIG. 2, software control of the production apparatus determines whether laser marking operations are being performed prior to trimming and forming a device using ram press down operations. This embodiment can provide a process which gives priority to laser marking, for example if laser marking operations generally require longer to perform per device than ram press down operations. In cases where laser marking requires substantially longer per device than ram press down operations, software control can be programmed to suspend active laser marking only after completing laser marking operations on more than one device. In an implementation of this particular embodiment, box 38 of FIG. 2 could be replaced by “complete active laser marking on X number of devices” where “X” is greater than one. For example, if laser marking operations take two times longer per device than ram press down operations, X can equal two to allow laser marking of two devices before initiating active ram press down operations. This may ensure that laser marking is performed at a sufficient rate that the implementation of the present teachings do not adversely affect production throughput

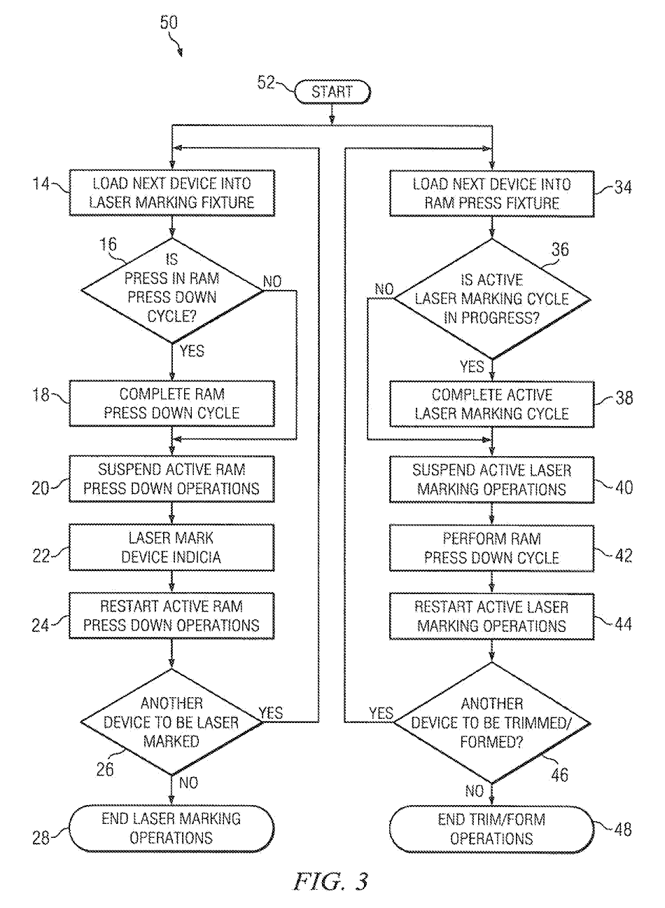

Another embodiment 50 is depicted in FIG. 3. This embodiment can incorporate both the FIG. 1 and FIG. 2 embodiments, including any optional processes, and may provide for an efficient manufacturing process. After starting 52 this process, the two processes described above with reference to FIGS. 1 and 2 run simultaneously. That is, software control checks to see whether laser marking is in progress 36 prior to performing a ram press down operations 42, and checks to see whether ram press down operations are in progress 16 prior to performing laser marking 22. Priority can be given to whichever process requires longer per device to perform.

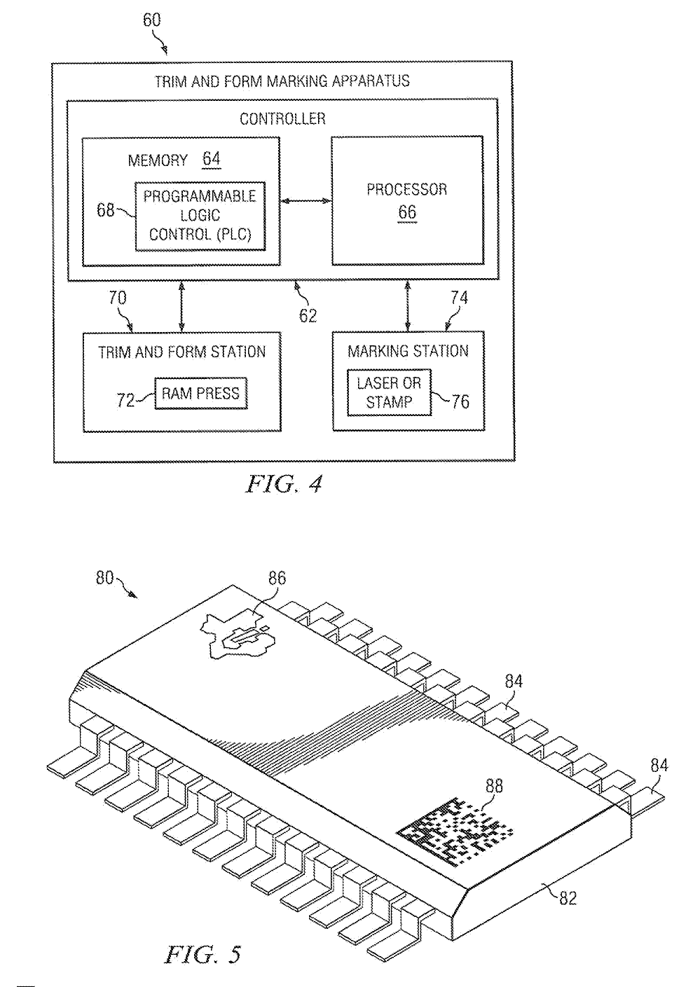

FIG. 4 depicts an embodiment of an apparatus 60 which performs trim and form operations as well as marking operations. The apparatus 60 can include a controller 62 including memory 64 and a processor 66 such as a microprocessor. Programmable logic control (PLC) 68 can be stored in the memory 64. The controller 62 can be used to control operation of both a trim and form station 70 including a ram press 72, and a marking station 74 which can include a laser or stamp 76. Control by the controller can include one of the embodiments described with reference to FIGS. 1-3. PLC control 68 can be provided as software or firmware instructions in memory 64 to control the trim and form station 70 and the marking station 74. In another embodiment, the controller 62 and components 64-68 can be provided by an external computer which controls the trim and form station 70 and the marking station 74, for example through a cable, wirelessly, or through the Internet.

FIG. 5 is a perspective view depicting a semiconductor device 80 including a plastic resin encapsulation 82 and external package leads 84 which have been formed using a trim and form station 70. Device 80 further includes human readable indicia 86 (i.e., company logo) and scannable coded indicia 88 printed using laser marking, ink marking, and the like. The coded indicia can be, for example, a numeric-only barcode, an alphanumeric (1D) barcode, a 2D barcode (depicted), or other coded indicia.

The embodiments of the present teachings thus provide a method which can improve the quality of indicia formed on a semiconductor device package. Such as a laser mark or ink mark on a plastic resin or ceramic semiconductor package, by coordinating timing of a laser marking operation with a ram press operation. In an embodiment, a system such as the system of FIG. 4, can be configured to execute instructions to detect marking of a semiconductor device package, trimming of a semiconductor device package, and lead forming of a semiconductor device package, and can be further configured to coordinate the laser marking operation and a ram press operation so as not to overlap (i.e., active laser marking operations end before beginning active ram press operations, and active ram press operations end before beginning active laser marking operations). The cost of implementing the present teachings can be small, requiring a software change to controlling software such as PLC software. No change to hardware configuration is required. Certain embodiments may be implemented or executed in the form of a computer program or software. The computer program or software may exist in a variety of forms, including in long-term storage, in execution by a computer system, and others. For example, the computer program can exist as software program(s) including program instructions in source code, object code, executable code or other formats; firmware program(s); or hardware description language (HDL) files. Any of the forgoing can be embodied on a computer readable medium, which can include storage devices, electronic memory, and signals, in compressed or uncompressed form. Exemplary computer readable storage devices or media include conventional computer system RAM (random access memory), ROM (read-only memory), EPROM (erasable, programmable ROM), EEPROM (electrically erasable, programmable ROM), magnetic disks or optical disks, solid-state disks, or magnetic storage tapes. Computer programs or software can be distributed or accessed for instance via hard disk, solid state storage devices, CD-ROM, or via Internet download. In respects, the Internet itself, as an entity, can be regarded a computer readable medium, as can local area networks (LANs) and other computer networks in general.

Another embodiment of the present teachings can include a non-transitory computer readable medium, wherein the computer readable medium includes instructions to cause a device to perform any of the method embodiments described above.

While various exemplary methods are illustrated and described herein as a series of acts or events, it will be appreciated that the present teachings are not limited by the illustrated ordering of such acts or events. For example, some acts may occur in different orders and/or concurrently with other acts or events apart from those illustrated and/or described herein, in accordance with the present teachings. In addition, not all illustrated stages may be required to implement a methodology in accordance with the present teachings.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume negative values, e.g. −1, −3, −10, −20, −30, etc.

While the present teachings have been illustrated with respect to one or more implementations, alterations and/or modifications can be made to the illustrated examples without departing from the spirit and scope of the appended claims. In addition, while a particular feature of the disclosure may have been described with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening material such that contact is possible but not required. Neither “on” nor “over” implies any directionality as used herein. The term “conformal” describes a coating material in which angles of the underlying material are preserved by the conformal material. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the present teachings will be apparent to those skilled in the art from consideration of the specification and practice of the disclosure herein. It is intended that the specification and examples be considered as exemplary only, with a true scope and spirit of the present teachings being indicated by the following claims.

Terms of relative position as used in this application are defined based on a plane parallel to the conventional plane or working surface of a wafer or substrate, regardless of the orientation of the wafer or substrate. The term “horizontal” or “lateral” as used in this application is defined as a plane parallel to the conventional plane or working surface of a wafer or substrate, regardless of the orientation of the wafer or substrate. The term “vertical” refers to a direction perpendicular to the horizontal. Terms such as “on,” “side” (as in “sidewall”), “higher,” “lower,” “over,” “top,” and “under” are defined with respect to the conventional plane or working surface being on the top surface of the wafer or substrate, regardless of the orientation of the wafer or substrate.

1. A method of compensating for vibration in an apparatus comprising a trim and form station and a marking station, the method comprising:
detecting a trim and form operation at a trim and form station;
detecting a marking operation at a marking station; and
coordinating the trim and form operation with the marking operation, such that the trim and form operation does not occur during the marking operation.

2. The method of claim 1, wherein the trim and form station comprises a ram press and the method further comprises:
detecting whether a ram press is trimming a leadframe;
if the ram press is not trimming a leadframe, suspending ram press operations;
if the ram press is trimming a leadframe, suspending ram press operations after the leadframe has been trimmed;
with the ram press operations suspended, marking indicia on a semiconductor device package; and
after marking the indicia on the semiconductor device package, restarting the ram press operations.

3. The method of claim 2, further comprising:
with the ram press operations suspended, marking indicia on more than one semiconductor device package before restarting the ram press operations.

4. The method of claim 1, wherein the trim and form station comprises a ram press and the method further comprises:
detecting whether the marking station is marking indicia on a semiconductor device package;
if the marking station is not marking indicia on a semiconductor device package, suspending marking operations;
if the ram press is marking indicia on a semiconductor device package, suspending marking operations after the semiconductor device package has been marked;
with marking operations suspended, trimming a leadframe with the ram press; and
after trimming the leadframe with the ram press, restarting the marking operations.

5. The method of claim 4, further comprising:
with the marking operations suspended, trimming more than one leadframe before restarting the marking operations.

6. A system for vibration compensation in a machine, the system comprising:
a marking station comprising at least one of a laser or a stamp, wherein the marking station is configured to mark a semiconductor device package with indicia;
a trim and form station comprising a ram press configured to trim a semiconductor device package and to form leads on a semiconductor device package;
memory comprising instructions for controlling each of the marking station and the trim and form station; and
a processor coupled to the memory and configured to execute the instructions to detect each of the marking of a semiconductor package, the trimming of a semiconductor device package, and the lead forming on a semiconductor device package on the machine and further configured to coordinate the laser marking operation and the ram press operation so as not to overlap.

7. The system of claim 6, wherein the system is further configured to perform the following steps:
detect whether a ram press is trimming a leadframe;
if the ram press is not trimming a leadframe, suspending ram press operations;
if the ram press is trimming a leadframe, suspending ram press operations after the leadframe has been trimmed;
with the ram press operations suspended, marking indicia on a semiconductor device package; and
after marking the indicia on the semiconductor device package, restarting the ram press operations.

8. The system of claim 7, wherein the system is further configured to perform the following steps:
with the ram press operations suspended, marking indicia on more than one semiconductor device package before restarting the ram press operations.

9. The system of claim 6, wherein the trim and form station comprises a ram press and the system is further configured to perform the following steps:
detecting whether the marking station is marking indicia on a semiconductor device package;
if the marking station is not marking indicia on a semiconductor device package, suspending marking operations;
if the ram press is marking indicia on a semiconductor device package, suspending marking operations after the semiconductor device package has been marked;
with marking operations suspended, trimming a leadframe with the ram press; and
after trimming the leadframe with the ram press, restarting the marking operations.

10. The system of claim 9, wherein the system is further configured to perform the following steps:
with the marking operations suspended, trimming more than one leadframe before restarting the marking operations.

11. A non-transitory computer readable medium, comprising instructions to cause a device to perform a method comprising:
detecting a trim and form operation at a trim and form station;
detecting a marking operation at a marking station; and
coordinating the trim and form operation with the marking operation, such that the trim and form operation does not occur during the marking operation.

12. The non-transitory computer readable medium of claim 11, wherein the instructions further cause the device to perform a method comprising:
detecting whether a ram press is trimming a leadframe;
if the ram press is not trimming a leadframe, suspending ram press operations;
if the ram press is trimming a leadframe, suspending ram press operations after the leadframe has been trimmed;
with the ram press operations suspended, marking indicia on a semiconductor device package; and
after marking the indicia on the semiconductor device package, restarting the ram press operations.

13. The non-transitory computer readable medium of claim 12, wherein the instructions further cause the device to perform a method comprising:
with the ram press operations suspended, marking indicia on more than one semiconductor device package before restarting the ram press operations.

14. The non-transitory computer readable medium of claim 11, wherein the instructions further cause the device to perform a method comprising:
detecting whether the marking station is marking indica on a semiconductor device package;
if the marking station is not marking indicia on a semiconductor device package, suspending marking operations;
if the ram press is marking indicia on a semiconductor device package, suspending marking operations after the semiconductor device package has been marked;
with marking operations suspended, trimming a leadframe with the ram press; and
after trimming the leadframe with the ram press, restarting the marking operations.

15. The non-transitory computer readable medium of claim 14, wherein the instructions further cause the device to perform a method comprising:
with the marking operations suspended, trimming more than one leadframe before restarting the marking operations.
